(19) United States
(12) Patent Application Publication
(10) Pub. No.: US 2023/0411148 A1
(43) Pub. Date: Dec. 21, 2023

(54) PROCESSING METHOD, METHOD OF MANUFACTURING SEMICONDUCTOR DEVICE, PROCESSING APPARATUS, AND RECORDING MEDIUM

(71) Applicant: Kokusai Electric Corporation, Tokyo (JP)

(72) Inventors: Atsushi SANO, Toyama-shi (JP); Katsuyoshi HARADA, Toyama-shi (JP); Daigo YAMAGUCHI, Toyama-shi (JP); Masaru KADOSHIMA, Toyama-shi (JP)

(73) Assignee: Kokusai Electric Corporation, Tokyo (JP)

(21) Appl. No.: 18/455,302

(22) Filed: Aug. 24, 2023

Related U.S. Application Data
(63) Continuation of application No. PCT/JP2021/011584, filed on Mar. 22, 2021.

(51) Int. Cl. H01L 21/02; H01J 37/32; C23C 16/32; C23C 16/56; C23C 16/52; C23C 16/36

(52) U.S. Cl. CPC H01L 21/0228; H01L 21/02274; H01J 37/32449; H01L 21/02219; H01J 2237/3321; C23C 16/56; C23C 16/52; C23C 16/36; C23C 16/325

(57) ABSTRACT

There is provided a technique that includes (a) forming an oligomer-containing layer on a surface of a substrate and in a concave portion of the substrate by allowing an oligomer to be generated, grow, and flow on the surface of the substrate and in the concave portion of the substrate by performing a cycle a predetermined number of times at a first temperature, the cycle including: supplying a precursor gas to the substrate; supplying a first nitrogen- and hydrogen-containing gas to the substrate; supplying a second nitrogen- and hydrogen-containing gas to the substrate; and supplying a first modifying gas to the substrate; and (b) forming a film by performing a thermal treatment to the substrate at a second temperature equal to or higher than the first temperature to modify the oligomer-containing layer so as to be filled in the concave portion.

### CROSS-REFERENCE TO RELATED APPLICATION

This application is a Bypass Continuation Application of PCT International Application No. PCT/JP2021/011584, filed on Mar. 22, 2021, the entire contents of which are incorporated herein by reference.

### TECHNICAL FIELD

The present disclosure relates to a processing method, a method of manufacturing a semiconductor device, a processing apparatus, and a recording medium.

### BACKGROUND

As a process of manufacturing a semiconductor device, a process of forming a film on a substrate using a plurality of kinds of gases may be often performed. In this case, a process of forming the film using the plurality of kinds of gases so as to be filled in a concave portion formed in the surface of the substrate may be often performed.

### SUMMARY

Some embodiments of the present disclosure provide a technique capable of improving a property of a film formed so as to be filled in a concave portion formed in the surface of a substrate.

According to one embodiment of the present disclosure, there is provided a technique that includes:
(a) forming an oligomer-containing layer on a surface of a substrate and in a concave portion of the substrate by allowing an oligomer, which contains an element contained in at least one selected from the group of a precursor gas, a first nitrogen- and hydrogen-containing gas, and a second nitrogen- and hydrogen-containing gas, to be generated, grow, and flow on the surface of the substrate and in the concave portion of the substrate by performing a cycle a predetermined number of times at a first temperature, the cycle including:
   supplying the precursor gas to the substrate provided with the concave portion in the surface of the substrate;
   supplying the first nitrogen- and hydrogen-containing gas to the substrate;
   supplying the second nitrogen- and hydrogen-containing gas to the substrate; and
   supplying a first modifying gas, which includes at least one selected from the group of a gas heated to a temperature higher than a temperature of the substrate and a gas excited into a plasma state, to the substrate; and
(b) forming a film, which is obtained by modifying the oligomer-containing layer, by performing a thermal treatment to the substrate, which has the oligomer-containing layer formed on the surface of the substrate and in the concave portion of the substrate, at a second temperature equal to or higher than the first temperature to modify the oligomer-containing layer formed on the surface of the substrate and in the concave portion of the substrate so as to be filled in the concave portion.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a substrate processing apparatus suitably used in each embodiment of the present disclosure, in which a portion of the process furnace is shown in a vertical cross section.

FIG. 2 is a schematic configuration view of the vertical process furnace of the substrate processing apparatus suitably used in each embodiment of the present disclosure, in which a portion of the process furnace is shown in a cross section taken along line A-A in FIG. 1.

FIG. 3 is a schematic configuration diagram of a controller of the substrate processing apparatus suitably used in each embodiment of the present disclosure, in which a control system of the controller is shown in a block diagram.

FIG. 4 is a diagram showing a substrate processing sequence according to a first embodiment of the present disclosure.

FIG. 5 is a diagram showing a substrate processing sequence according to a second embodiment of the present disclosure.

FIG. 6 is a diagram showing a substrate processing sequence according to a third embodiment of the present disclosure.

FIG. 7 is a diagram showing a substrate processing sequence according to a fourth embodiment of the present disclosure.

FIG. 8 is a diagram showing a substrate processing sequence according to a fifth embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment of the Present Disclosure

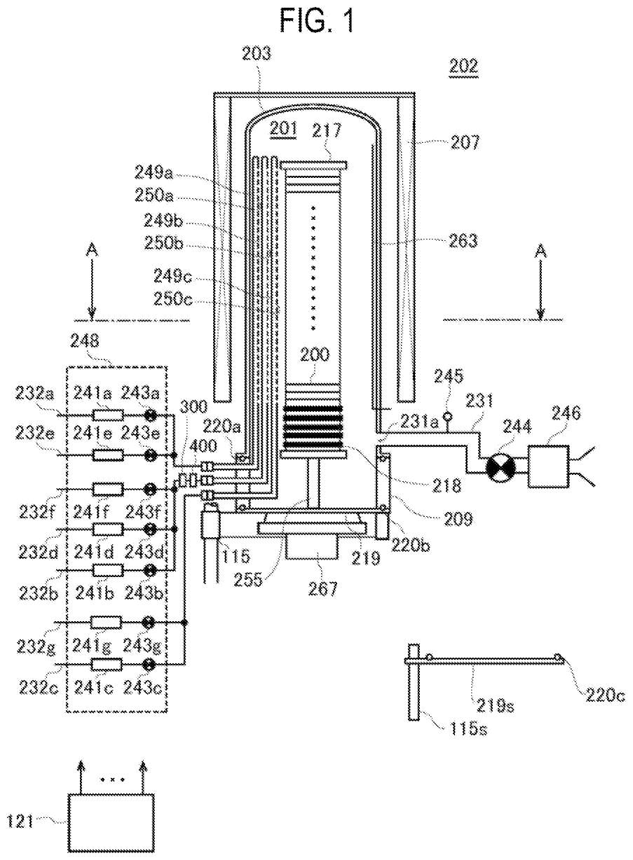

A first embodiment of the present disclosure will now be described mainly with reference to FIGS. 1 to 4. The drawings used in the following descriptions are all schematic, and the dimensional relationship, ratios, and the like of various elements shown in figures do not always match the actual ones. Further, the dimensional relationship, ratios, and the like of various elements between plural figures do not always match each other.

### (1) Configuration of Substrate Processing Apparatus

As shown in FIG. 1, a process furnace 202 includes a heater 207 as a heating mechanism (a temperature regulator). The heater 207 has a cylindrical shape and is installed vertically by being supported by a holding plate. The heater 207 also functions as an activation mechanism (an excitation part) configured to thermally activate (excite) a gas.

A reaction tube 203 is disposed inside the heater 207 to be concentric with the heater 207. The reaction tube 203 is made of, for example, a heat resistant material such as quartz (SiO₂) or silicon carbide (SiC), and has a cylindrical shape with its upper end closed and its lower end opened. A manifold 209 is disposed to be concentric with the reaction tube 203 under the reaction tube 203. The manifold 209 is made of, for example, a metal material such as stainless steel (SUS), and has a cylindrical shape with both of its upper and lower ends opened. The upper end portion of the manifold 209 is engaged with the lower end portion of the reaction tube 203 so as to support the reaction tube 203. An O-ring 220a serving as a seal member is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical portion of the process container. The process chamber 201 is configured to accommodate a plurality of wafers 200 as substrates. Processing on the wafers 200 is performed in the process chamber 201.

Nozzles 249a to 249c as first to third supply parts are installed in the process chamber 201 so as to penetrate through a sidewall of the manifold 209. The nozzles 249a to 249c are also referred to as first to third nozzles, respectively. The nozzles 249a to 249c are made of, for example, a non-metallic material which is a heat-resistant material such as quartz or SiC. Gas supply pipes 232a to 232c are connected to the nozzles 249a to 249c, respectively. The nozzles 249a to 249c are different nozzles from each other, and each of the nozzles 249a and 249c is installed adjacent to the nozzle 249b.

Mass flow controllers (MFCs) 241a to 241c, which are flow rate controllers (flow rate control parts), and valves 243a to 243c, which are opening/closing valves, are installed in the gas supply pipes 232a to 232c, respectively, sequentially from the upstream side of a gas flow. A gas supply pipe 232e is connected to the gas supply pipe 232a at the downstream side of the valve 243a. Each of gas supply pipes 232d and 232f is connected to the gas supply pipe 232b at the downstream side of the valve 243b. A gas supply pipe 232g is connected to the gas supply pipe 232c at the downstream side of the valves 243c. MFCs 241d to 241g and valves 243d to 243g are installed in the gas supply pipes 232d to 232g, respectively, sequentially from the upstream side of a gas flow. The gas supply pipes 232a to 232g are made of, for example, a metal material such as SUS.

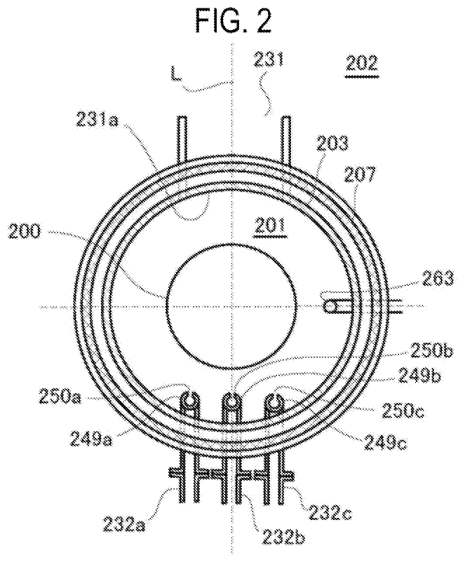

As shown in FIG. 2, each of the nozzles 249a to 249c is arranged in a space having an annular shape in a plan view between an inner wall of the reaction tube 203 and the wafers 200, and is installed so as to extend upward from a lower portion of the inner wall of the reaction tube 203 to an upper portion of inner wall of the reaction tube 203, that is, along an arrangement direction of the wafers 200. Specifically, each of the nozzles 249a to 249c is installed in a region horizontally surrounding a wafer arrangement region, in which the wafers 200 are arranged, at a lateral side of the wafer arrangement region, along the wafer arrangement region. In a plan view, the nozzle 249b is arranged so as to face an exhaust port 231a to be described later in a straight line with the centers of the wafers 200 loaded into the process chamber 201, which are interposed therebetween. The nozzles 249a and 249c are arranged so as to sandwich a straight line L passing through the nozzle 249b and the center of the exhaust port 231a from both sides along the inner wall of the reaction tube 203 (the outer peripheral portion of the wafers 200). The straight line L is also a straight line passing through the nozzle 249b and the centers of the wafers 200. That is, it can be said that the nozzle 249c is installed on the side opposite to the nozzle 249a with the straight line L interposed therebetween. The nozzles 249a and 249c are arranged in line symmetry with the straight line L as an axis of symmetry. Gas supply holes 250a to 250c for supplying a gas are formed on the side surfaces of the nozzles 249a to 249c, respectively. Each of the gas supply holes 250a to 250c is opened so as to oppose (face) the exhaust port 231a in a plan view, which enables a gas to be supplied toward the wafers 200. A plurality of gas supply holes 250a to 250c are formed from the lower portion of the reaction tube 203 to the upper portion of the reaction tube 203.

A precursor gas is supplied from the gas supply pipe 232a into the process chamber 201 via the MFC 241a, the valve 243a, and the nozzle 249a.

A first nitrogen (N)- and hydrogen (H)-containing gas is supplied from the gas supply pipe 232b into the process chamber 201 via the MFC 241b, the valve 243b, and the nozzle 249b.

A second nitrogen (N)- and hydrogen (H)-containing gas is supplied from the gas supply pipe 232c into the process chamber 201 via the MFC 241c, the valve 243c, and the nozzle 249c.

A modifying gas is supplied from the gas supply pipe 232d into the process chamber 201 via the MFC 241d, the valve 243d, the gas supply pipe 232b, and the nozzle 249b.

An inert gas is supplied from the gas supply pipes 232e to 232g into the process chamber 201 via the MFCs 241e to 241g, the valves 243e to 243g, the gas supply pipes 232a to 232c, and the nozzles 249a to 249c, respectively. The inert gas acts as a purge gas, a carrier gas, a dilution gas, or the like.

A heater 300 as a thermal excitation part that heats a gas to a temperature higher than the temperature of the wafers 200, and a remote plasma unit (RPU) 400 as a plasma excitation part (a plasma generator) that excites a gas into a plasma state are installed on a downstream side of a connection portion of the gas supply pipe 232b with the gas supply pipe 232f. Exciting a gas into a plasma state is also simply referred to as plasma excitation. Heating a gas to thermally excite the gas is also simply referred to as thermal excitation. The heater 300 and the RPU 400 may be installed in the gas supply pipe 232d. In that case, it is desirable to provide the heater 300 and the RPU 400 on the downstream side of the valve 243d of the gas supply pipe 232d. By applying radio-frequency (RF) power to the RPU 400, it is possible to plasma-excite the gas inside the RPU 400, that is, to excite the gas into a plasma state. As a plasma generation method, a capacitively-coupled plasma (abbreviation: CCP) method may be used, or an inductively-coupled plasma (abbreviation: ICP) method may be used.

The heater 300 is configured to be capable of heating the modifying gas supplied from the gas supply pipe 232d to a temperature higher than the temperature of the wafers 200 and supplying the heated modifying gas as a first modifying gas or a second modifying gas. The heater 300 is also configured to be capable of heating the first N- and H-containing gas supplied from the gas supply pipe 232b or the inert gas supplied from the gas supply pipe 232f to a temperature higher than the temperature of the wafers 200 and supplying the heated gas.

The RPU 400 is configured to be capable of exciting the modifying gas supplied from the gas supply pipe 232d into a plasma state and supplying the excited modifying gas as the first modifying gas or the second modifying gas. The RPU 400 is also configured to be capable of exciting the first N- and H-containing gas supplied from the gas supply pipe 232b or the inert gas supplied from the gas supply pipe 232f into a plasma state and supplying the excited gas.

The first modifying gas and the second modifying gas may be the same substance (substances with the same molecular structure), or may be different substances (substances with different molecular structures). Further, each of the first modifying gas and the second modifying gas may be a gas heated to a temperature higher than the temperature of the wafers 200, or may be a gas excited into a plasma state. Alternatively, one of the first modifying gas and the second modifying gas may be a gas heated to a temperature higher than the temperature of the wafers 200, and the other may be excited into a plasma state.

FIG. 1 shows an example in which the heater 300 and the RPU 400 are installed in the gas supply pipe 232b, but the heater 300 and the RPU 400 may be separately installed in different gas supply pipes. In this case, the gas heated to a temperature higher than the temperature of the wafers 200 and the gas excited into a plasma state can be separately supplied from different gas supply pipes. With this configuration, the gas heated to a temperature higher than the temperature of the wafers 200 and the gas excited into a plasma state can be separately and simultaneously supplied from different gas supply pipes. Further, with this configuration, it becomes possible to separately and non-simultaneously supply the gas heated to a temperature higher than the temperature of the wafers 200 and the gas excited into a plasma state from different gas supply pipes.

A precursor gas supply system is mainly constituted by the gas supply pipe 232a, the MFC 241a, and the valve 243a. A first N- and H-containing gas supply system is mainly constituted by the gas supply pipe 232b, the MFC 241b, and the valve 243b. A second N- and H-containing gas supply system is mainly constituted by the gas supply pipe 232c, the MFC 241c, and the valve 243c. A modifying gas supply system is mainly constituted by the gas supply pipe 232d, the MFC 241d, and the valve 243d. A first modifying gas supply system and a second modifying gas supply system are mainly constituted by at least one selected from the group of the gas supply pipe 232d, the MFC 241d, the valve 243d, the heater 300, and the RPU 400. An inert gas supply system is mainly constituted by the gas supply pipes 232e to 232g, the MFCs 241e to 241g, and the valves 243e to 243g.

Any or all of the above-described various supply systems may be configured as an integrated-type supply system 248 in which the valves 243a to 243g, the MFCs 241a to 241g, and so on are integrated. The integrated-type supply system 248 is connected to each of the gas supply pipes 232a to 232g. In addition, the integrated-type supply system 248 is configured such that operations of supplying various gases into the gas supply pipes 232a to 232g (that is, the opening/closing operation of the valves 243a to 243g, the flow rate adjustment operation by the MFCs 241a to 241g, and the like) are controlled by a controller 121 which will be described later. The integrated-type supply system 248 is configured as an integral type or detachable-type integrated unit, and may be attached to and detached from the gas supply pipes 232a to 232g and the like on an integrated unit basis, so that the maintenance, replacement, extension, etc. of the integrated-type supply system 248 can be performed on an integrated unit basis.

The exhaust port 231a for exhausting an internal atmosphere of the process chamber 201 is installed in the lower portion of the side wall of the reaction tube 203. As shown in FIG. 2, in a plan view, the exhaust port 231a is installed at a position opposing (facing) the nozzles 249a to 249c (the gas supply holes 250a to 250c) with the wafers 200 interposed therebetween. The exhaust port 231a may be installed to extend from the lower portion of the side wall of the reaction tube 203 to an upper portion of the side wall of the reaction tube 203, that is, along the wafer arrangement region. An exhaust pipe 231 is connected to the exhaust port 231a. A vacuum exhaust device, for example, a vacuum pump 246, is connected to the exhaust pipe 231 via a pressure sensor 245, which is a pressure detector (pressure detection part) for detecting the internal pressure of the process chamber 201, and an auto pressure controller (APC) valve 244, which is a pressure regulator (pressure adjustment part). The APC valve 244 is configured to perform or stop a vacuum exhaust operation in the process chamber 201 by opening/closing the valve while the vacuum pump 246 is actuated, and is also configured to adjust the internal pressure of the process chamber 201 by adjusting an opening degree of the valve based on pressure information detected by the pressure sensor 245 while the vacuum pump 246 is actuated. An exhaust system is mainly constituted by the exhaust pipe 231, the APC valve 244, and the pressure sensor 245. The vacuum pump 246 may be considered to be included in the exhaust system.

A seal cap 219, which serves as a furnace opening cover configured to hermetically seal a lower end opening of the manifold 209, is installed under the manifold 209. The seal cap 219 is made of, for example, a metal material such as SUS, and is formed in a disc shape. An O-ring 220b, which is a seal member making contact with the lower end of the manifold 209, is installed on an upper surface of the seal cap 219. A rotator 267 configured to rotate a boat 217, which will be described later, is installed under the seal cap 219. A rotary shaft 255 of the rotator 267 is connected to the boat 217 via the seal cap 219. The rotator 267 is configured to rotate the wafers 200 by rotating the boat 217. The seal cap 219 is configured to be vertically moved up and down by a boat elevator 115 which is an elevating mechanism installed outside the reaction tube 203. The boat elevator 115 is configured as a transfer device (transfer mechanism) which loads/unloads (transfers) the wafers 200 into/out of the process chamber 201 by moving the seal cap 219 up and down.

A shutter 219s, which serves as a furnace opening cover configured to hermetically seal a lower end opening of the manifold 209 in a state where the seal cap 219 is lowered and the boat 217 is unloaded from the process chamber 201, is installed under the manifold 209. The shutter 219s is made of, for example, a metal material such as SUS, and is formed in a disc shape. An O-ring 220c, which is a seal member making contact with the lower end of the manifold 209, is installed on an upper surface of the shutter 219s. The opening/closing operation (such as elevation operation, rotation operation, or the like) of the shutter 219s is controlled by a shutter opener/closer 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed below the boat 217 in multiple stages.

A temperature sensor 263 serving as a temperature detector is installed in the reaction tube 203. Based on temperature information detected by the temperature sensor 263, a state of supplying electric power to the heater 207 is adjusted such that an interior of the process chamber 201 has a desired temperature distribution. The temperature sensor 263 is installed along the inner wall of the reaction tube 203.

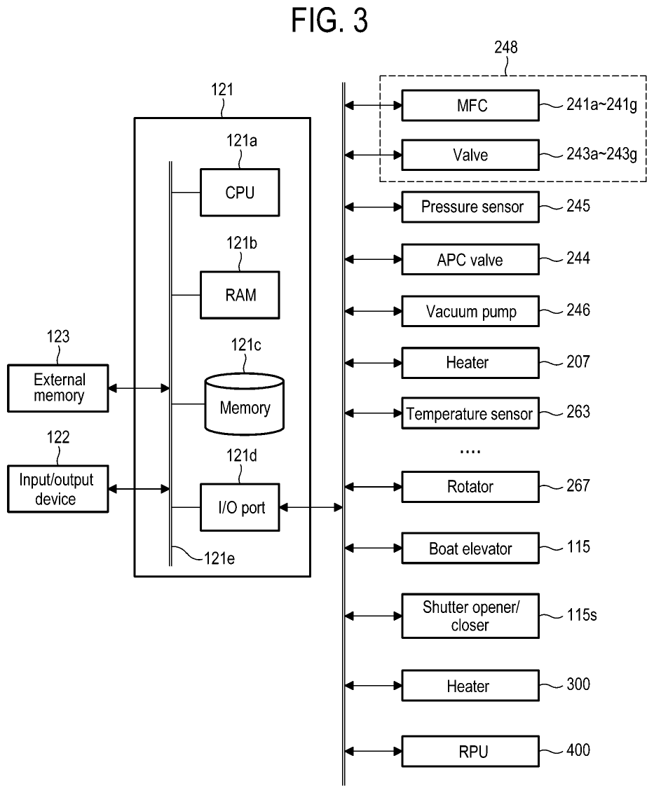

As shown in FIG. 3, a controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, for example, a touch panel or the like, is connected to the controller 121. Further, an external memory 123 may be connected to the controller 121.

The memory 121c is configured by, for example, a flash memory, a hard disk drive (HDD), a solid state drive (SSD), or the like. A control program for controlling operations of a substrate processing apparatus, a process recipe in which sequences and conditions of substrate processing to be described later are written, and the like are readably stored in the memory 121c. The process recipe functions as a program for causing the controller 121 to execute each sequence in the substrate processing, which will be described later, to obtain an expected result. Hereinafter, the process recipe and the control program may be generally and simply referred to as a “program.” Furthermore, the process recipe may be simply referred to as a “recipe.” When the term “program” is used herein, it may indicate a case of including the recipe alone, a case of including the control program alone, or a case of including both the recipe and the control program. The RAM 121b is configured as a memory area (work area) in which programs or data read by the CPU 121a are temporarily stored.

The I/O port 121d is connected to the MFCs 241a to 241g, the valves 243a to 243g, the pressure sensor 245, the APC valve 244, the vacuum pump 246, the temperature sensor 263, the heater 207, the rotator 267, the boat elevator 115, the shutter opener/closer 115s, the heater 300, the RPU 400, and so on.

The CPU 121a is configured to read and execute the control program from the memory 121c. The CPU 121a is also configured to read the recipe from the memory 121c according to an input of an operation command from the input/output device 122. The CPU 121a is configured to control the flow rate adjusting operation of various kinds of gases by the MFCs 241a to 241g, the opening/closing operation of the valves 243a to 243g, the opening/closing operation of the APC valve 244, the pressure adjusting operation performed by the APC valve 244 based on the pressure sensor 245, the actuating and stopping operation of the vacuum pump 246, the temperature adjusting operation performed by the heater 207 based on the temperature sensor 263, the operation of rotating the boat 217 with the rotator 267 and adjusting the rotation speed of the boat 217, the operation of moving the boat 217 up and down by the boat elevator 115, the opening/closing operation of the shutter 219s by the shutter opener/closer 115s, the gas heating operation by the heater 300, the gas plasma exciting operation by the RPU 400, and so on, according to contents of the read recipe.

The controller 121 may be configured by installing, on the computer, the aforementioned program stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is configured as a non-transitory computer-readable recording medium. Hereinafter, the memory 121c and the external memory 123 may be generally and simply referred to as a “recording medium”. When the term “recording medium” is used herein, it may indicate a case of including the memory 121c only, a case of including the external memory 123 only, or a case of including both the memory 121c and the external memory 123. Furthermore, the program may be provided to the computer using communication means such as the Internet or a dedicated line, instead of using the external memory 123.

### (2) Substrate Processing Process

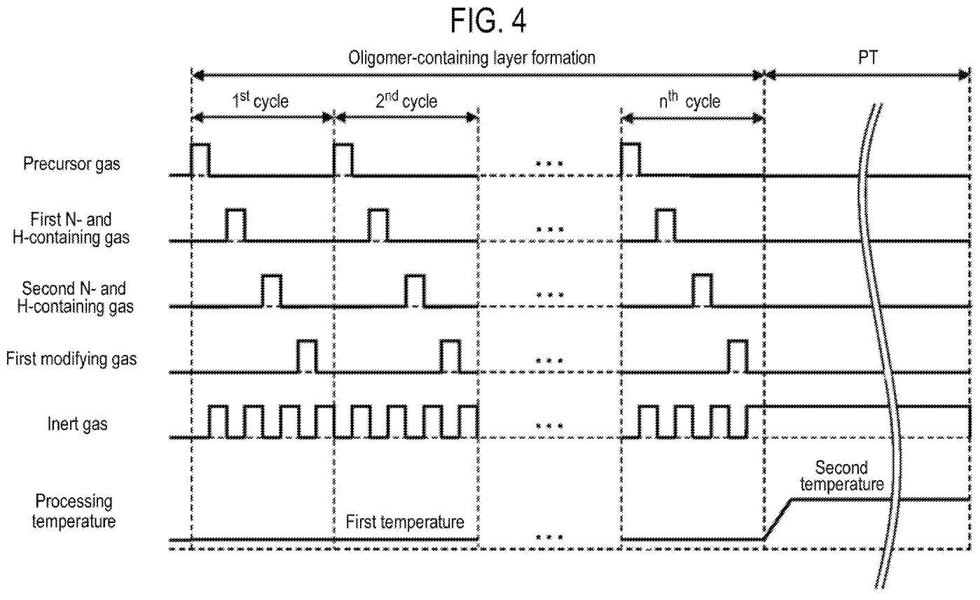

As a process of manufacturing a semiconductor device using the above-described substrate processing apparatus, an example of a processing sequence for forming a film on the surface of a wafer 200 as a substrate will be described mainly with reference to FIG. 4. In this embodiment, an example of using a silicon substrate (silicon wafer) as the wafer 200, in which a concave portion such as a trench, a hole or the like is provided in a surface of the silicon substrate, will be described. In the following descriptions, the operations of the respective parts constituting the substrate processing apparatus are controlled by the controller 121.

As shown in FIG. 4, a processing sequence of the present embodiment includes:
a step (oligomer-containing layer formation) of forming an oligomer-containing layer on the surface of a wafer 200 and in a concave portion of the wafer 200 by allowing an oligomer, which contains an element contained in at least one selected from the group of a precursor gas, a first N- and H-containing gas, and a second N- and H-containing gas, to be generated, grow, and flow on the surface of the wafer 200 and in the concave portion of the wafer 200 by performing a cycle a predetermined number of times (n times, where n is an integer of 1 or more) at a first temperature, the cycle including:
   a step of supplying the precursor gas to the wafer 200 provided with the concave portion in the surface of the wafer 200 (precursor gas supply);
   a step of supplying the first N- and H-containing gas to the wafer 200 (first N- and H-containing gas supply);
   a step of supplying the second N- and H-containing gas to the wafer 200 (second N- and H-containing gas supply); and
   a step of supplying a first modifying gas, which includes at least one selected from the group of a gas heated to a temperature higher than a temperature of the wafer 200 and a gas excited into a plasma state, to the wafer 200 (first modifying gas supply); and
a step (post-treatment) of forming a film, which is obtained by modifying the oligomer-containing layer, by performing thermal treatment (annealing) to the wafer 200, which has the oligomer-containing layer formed on the surface of the wafer 200 and in the concave portion of the wafer, at a second temperature equal to or higher than the first temperature to modify the oligomer-containing layer formed on the surface of the wafer 200 and in the concave portion of the wafer 200 so as to be filled in the concave portion.

In the present disclosure, the post-treatment is also referred to as PT.

Further, in the processing sequence shown in FIG. 4, the precursor gas supply, the first N- and H-containing gas supply, the second N- and H-containing gas supply, and the first modifying gas supply are performed non-simultaneously.

In the present disclosure, for the sake of convenience, the above-described processing sequence may also be denoted as follows. The same denotation is used in modifications and the like, including second, third, fourth, and fifth embodiments to be described later.

(Precursor gas→First N- and H-containing gas→Second N- and H-containing gas→First modifying gas)×n→PT

When the term “wafer” is used in the present disclosure, it may refer to “a wafer itself” or “a wafer and a stacked body of certain layers or films formed on a surface of the wafer”. When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

### (Wafer Charging and Boat Loading)

After the boat 217 is charged with a plurality of wafers 200 (wafer charging), the shutter 219s is moved by the shutter opener/closer 115s and the lower end opening of the manifold 209 is opened (shutter open). Thereafter, as shown in FIG. 1, the boat 217 charged with the plurality of wafers 200 is lifted up by the boat elevator 115 and loaded into the process chamber 201 (boat loading). In this state, the seal cap 219 seals the lower end of the manifold 209 via the O-ring 220b.

### (Pressure Adjustment and Temperature Adjustment)

After the boat loading is completed, the interior of the process chamber 201, that is, a space where the wafers 200 are placed, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the measured pressure information (pressure adjustment). Further, the wafers 200 in the process chamber 201 are heated by the heater 207 so as to have a desired processing temperature. At this time, the state of supplying electric power to the heater 207 is feedback-controlled based on the temperature information detected by the temperature sensor 263 so that the interior of the process chamber 201 has a desired temperature distribution (temperature adjustment). Further, the rotation of the wafers 200 by the rotator 267 is started. The exhaust of the interior of the process chamber 201 and the heating and rotation of the wafers 200 are continuously performed at least until the processing on the wafers 200 is completed.

### (Oligomer-Containing Layer Formation)

After that, the following steps 1 to 4 are sequentially executed.

### [Step 1]

In this step, a precursor gas is supplied to the wafer 200 in the process chamber 201.

Specifically, the valve 243a is opened to allow the precursor gas to flow into the gas supply pipe 232a. The flow rate of the precursor gas is adjusted by the MFC 241a, and the precursor gas is supplied into the process chamber 201 via the nozzle 249a and is exhausted through the exhaust port 231a. In this operation, the precursor gas is supplied to the wafer 200 (precursor gas supply). At this time, the valves 243e to 243g may be opened to allow an inert gas to be supplied into the process chamber 201 via the nozzles 249a to 249c, respectively.

After a predetermined time has elapsed, the valve 243a is closed to stop the supply of the precursor gas into the process chamber 201. Then, the interior of the process chamber 201 is vacuum-exhausted to remove a gas and the like remaining in the process chamber 201 from the interior of the process chamber 201. At this time, the valves 243e to 243g are opened to allow an inert gas to be supplied into the process chamber 201 via the nozzles 249a to 249c. The inert gas supplied from the nozzles 249a to 249c acts as a purge gas, thereby purging the space in which the wafers 200 are placed, that is, the interior of the process chamber 201 (purging).

As the precursor gas, for example, a silane-based gas containing silicon (Si) as a main element forming a film formed on the surface of the wafer 200 may be used. As the silane-based gas, for example, a gas containing Si and halogen, that is, a halosilane-based gas, may be used. The halogen includes chlorine (Cl), fluorine (F), bromine (Br), iodine (I), and the like. That is, the halosilane-based gas includes a chlorosilane-based gas, a fluorosilane-based gas, a bromosilane-based gas, an iodosilane-based gas, and the like. As the halosilane-based gas, for example, a gas containing silicon, carbon (C), and halogen, that is, an organic halosilane-based gas, may be used. As the organic halosilane-based gas, for example, a gas containing Si, C, and Cl, that is, an organic chlorosilane-based gas, may be used.

Examples of the precursor gas may include a C- and halogen-free silane-based gas such as a monosilane (SiH₄, abbreviation: MS) gas, a disilane (Si₂H₆, abbreviation: DS) gas, or the like, a C-free halosilane gas such as a dichlorosilane (SiH₂Cl₂, abbreviation: DCS) gas, a hexachlorodisilane (Si₂Cl₆, abbreviation: HCDS) gas, or the like, an alkylsilane-based gas such as a trimethylsilane (SiH(CH₃)₃, abbreviation: TMS) gas, a dimethylsilane (SiH₂(CH₃)₂, abbreviation: DMS) gas, a triethylsilane (SiH(C₂H₅)₃, abbreviation: TES) gas, a diethylsilane (SiH₂(C₂H₅)₂, abbreviation: DES) gas, or the like, an alkylenehalosilane-based gas such as a bis(trichlorosilyl)methane ((SiCl₃)₂CH₂, abbreviation: BTCSM) gas, a 1,2-bis(trichlorosilyl)ethane ((SiCl₃)₂C₂H₄, abbreviation: BTCSE) gas, or the like, and an alkylhalosilane-based gas such as a trimethylchlorosilane (SiCl(CH₃)₃, abbreviation: TMCS) gas, a dimethyldichlorosilane (SiCl₂(CH₃)₂, abbreviation: DMDCS) gas, a triethylchlorosilane (SiCl(C₂H₅)₃, abbreviation: TECS) gas, a diethyldichlorosilane (SiCl₂(C₂H₅)₂, abbreviation: DEDCS) gas, a 1,1,2,2-tetrachloro-1,2-dimethyldisilane ((CH₃)₂Si₂Cl₄, abbreviation: TCDMDS) gas, a 1,2-dichloro-1,1,2,2-tetramethyldisilane ((CH₃)₄Si₂Cl₂, abbreviation: DCTMDS) gas, or the like. One or more of these gases may be used as the precursor gas.

Some of these precursor gases do not contain an amino group and contain halogen. Further, some of these precursor gases contain a chemical bond between silicon and silicon (Si—Si bond). Further, some of these precursor gases contain silicon and halogen, or contain silicon, halogen, and carbon. Further, some of these precursor gases contain an alkyl groups and halogen.

In case that the precursor gas does not contain an amino group, impurities are less likely to remain in the oligomer-containing layer, as compared with a case that the precursor gas contains an amino group. Further, in case that the precursor gas does not contain the amino group, it is possible to improve the controllability of the composition ratio of the oligomer-containing layer or a finally formed film, as compared with a case that the precursor gas contains the amino group. Further, in case that the precursor gas contains halogen, it is possible to increase the reactivity when the oligomer is formed in the oligomer-containing layer formation, thereby forming the oligomer efficiently, as compared with a case that the precursor gas does not contain halogen. Further, in case that the precursor gas contains a Si—Si bond, it is possible to increase the reactivity when the oligomer is formed in the oligomer-containing layer formation, thereby forming the oligomer efficiently, as compared with a case that the precursor gas does not contain a Si—Si bond. Further, in case that the precursor gas contains an alkyl group and halogen, it is possible to impart appropriate fluidity to the oligomer to be formed.

As the inert gas, a nitrogen (N₂) gas or a rare gas such as an argon (Ar) gas, a helium (He) gas, a neon (Ne) gas, a xenon (Xe) gas, or the like may be used. This point also applies to each step to be described later. One or more of these gases may be used as the inert gas.

### [Step 2]

In this step, a first N- and H-containing gas is supplied to the wafer 200 in the process chamber 201.

Specifically, the valve 243b is opened to allow the first N- and H-containing gas to flow into the gas supply pipe 232b. The flow rate of the first N- and H-containing gas is adjusted by the MFC 241b, and the first N- and H-containing gas is supplied into the process chamber 201 via the nozzle 249b and is exhausted through the exhaust port 231a. In this operation, the first N- and H-containing gas is supplied to the wafer 200 (first N- and H-containing gas supply). At this time, the valves 243e to 243g may be opened to allow an inert gas to be supplied into the process chamber 201 via the nozzles 249a to 249c, respectively.

After a predetermined time has elapsed, the valve 243b is closed to stop the supply of the first N- and H-containing gas into the process chamber 201. Then, a gas and the like remaining in the process chamber 201 are removed from the interior of the process chamber 201 according to the same processing procedure and process conditions as the purging in step 1.

Examples of the first N- and H-containing gas may include a hydrogen nitride-based gas such as an ammonia (NH₃) gas, an ethylamine-based gas such as a monoethylamine (C₂H₅NH₂, abbreviation: MEA) gas, a diethylamine ((C₂H₅)₂NH, abbreviation: DEA) gas, a triethylamine ((C₂H₅)₃N, abbreviation: TEA) gas, or the like, a methylamine-based gas such as a monomethylamine (CH₃NH₂, abbreviation: MMA) gas, a dimethylamine ((CH₃)₂NH, abbreviation: DMA) gas, a trimethylamine ((CH₃)₃N, abbreviation: TMA) gas, or the like, a cyclic amine-based gas such as a pyridine (CSHSN) gas, a piperazine (C₄H₁₀N₂) gas, or the like, and an organic hydrazine-based gas such as a monomethylhydrazine ((CH₃)HN₂H₂, abbreviation: MMH) gas, a dimethylhydrazine ((CH₃)₂N₂H₂, abbreviation: DMH) gas, a trimethylhydrazine ((CH₃)₂N₂(CH₃)H, abbreviation: TMH) gas, or the like. One or more of these gases may be used as the first N- and H-containing gas. Since the amine-based gas and the organic hydrazine-based gas are composed of C, N, and H, these gases may also be referred to as a C-, N-, and H-containing gas.

### [Step 3]

In this step, a second N- and H-containing gas is supplied to the wafer 200 in the process chamber 201.

Specifically, the valve 243c is opened to allow the second N- and H-containing gas to flow into the gas supply pipe 232c. The flow rate of the second N- and H-containing gas is adjusted by the MFC 241c, and the second N- and H-containing gas is supplied into the process chamber 201 via the nozzle 249c and is exhausted through the exhaust port 231a. In this operation, the second N- and H-containing gas is supplied to the wafer 200 (second N- and H-containing gas supply). At this time, the valves 243e to 243g may be opened to sallow an inert gas to be supplied into the process chamber 201 via the nozzles 249a to 249c, respectively.

After a predetermined time has elapsed, the valve 243c is closed to stop the supply of the second N- and H-containing gas into the process chamber 201. Then, a gas and the like remaining in the process chamber 201 are removed from the interior of the process chamber 201 according to the same processing procedure and process conditions as the purging in step 1.

As the second N- and H-containing gas, for example, a hydrogen nitride-based gas such as an ammonia (NH₃) gas, a diazene (N₂H₂) gas, a hydrazine (N₂H₄) gas, an N₃H₅ gas, or the like may be used. As the second N- and H-containing gas, it is desirable to use a gas having a molecular structure different from that of the first N- and H-containing gas. However, depending on the process conditions, as the second N- and H-containing gas, it is also possible to use a gas having the same molecular structure as the first N- and H-containing gas. One or more of these gases may be used as the second N- and H-containing gas.

### [Step 4]

In this step, a first modifying gas containing at least one selected from the group of a gas heated to a temperature higher than the temperature of the wafer 200 and a gas excited into a plasma state is supplied to the wafer 200 in the process chamber 201.

Specifically, the valve 243d is opened to allow the modifying gas to flow into the gas supply pipe 232d. The flow rate of the modifying gas is adjusted by the MFC 241d, and the modifying gas is supplied into the process chamber 201 via the nozzle 249b and is exhausted through the exhaust port 231a. At this time, the modifying gas is heated to the temperature higher than the temperature of the wafer 200 by the heater 300 or is excited into the plasma state by the RPU 400, or both of them are performed. As a result, the modifying gas, as the first modifying gas containing at least one selected from the group of the gas heated to the temperature higher than the temperature of the wafer 200 and the gas excited into the plasma state, is supplied to the wafer 200 in the process chamber 201 via the nozzle 249b (first modifying gas supply). At this time, the valves 243e to 243g may be opened to allow an inert gas to be supplied into the process chamber 201 via the nozzles 249a to 249c, respectively.

After a predetermined time has elapsed, the valve 243d is closed to stop the supply of the modifying gas to the heater 300 or the RPU 400 and stop the supply of the first modifying gas into the process chamber 201. Then, a gas and the like remaining in the process chamber 201 is removed from the interior of the process chamber 201 according to the same processing procedure and process conditions as the purging in step 1.

As the modifying gas, for example, at least one selected from the group of an inert gas, a N- and H-containing gas, and a H-containing gas may be used. As the inert gas, for example, the same gas as the above-mentioned inert gas may be used. As the N- and H-containing gas, for example, the same gas as the above-mentioned first N- and H-containing gas or second N- and H-containing gas may be used. As the H-containing gas, for example, a hydrogen (H₂) gas, a deuterium (²H₂) gas, or the like may be used. The ²H₂ gas may also be written as a D₂ gas. One or more of these gases may be used as the modifying gas.

By using these gases as the modifying gas, at least one selected from the group of the gas heated to the temperature higher than the temperature of the wafer 200 and the gas excited into the plasma state, as the first modifying gas, may be supplied to the wafer 200. Further, by plasma-exciting these gases by the RPU 400, the first modifying gas contains active species such as N*, N₂*, Ar*, He*, Ne*, Xe*, NH*, NH₂*, NH₃*, H*, and H₂*. Further, depending on the heating conditions, these active species may be contained in the first modifying gas by thermally exciting these gases by the heater 300. *means radicals. The same applies to the following descriptions.

### [Performing Predetermined Number of Times]

After that, a cycle that performs the above-described steps 1 to 4 non-simultaneously, that is, non-synchronously, is performed a predetermined number of times (n times, where n is an integer of 1 or more).

At this time, when the precursor gas exists alone, the cycle is performed a predetermined number of times under a condition (temperature) where physical adsorption of the precursor gas is predominant (preferential) over chemical adsorption of the precursor gas. Specifically, when the precursor gas exists alone, the cycle is performed a predetermined number of times under a condition (temperature) where physical adsorption of the precursor gas is predominant (preferential) over thermal decomposition of the precursor gas and chemical adsorption of the precursor gas. Further, specifically, when the precursor gas exists alone, the cycle is performed a predetermined number of times under a condition (temperature) where physical adsorption of the precursor gas is predominant (preferential) over chemical adsorption of the precursor gas without thermal decomposition of the precursor gas. Further, specifically, the cycle is performed a predetermined number of times under a condition (temperature) that causes fluidity in the oligomer-containing layer. Further, specifically, the cycle is performed a predetermined number of times under a condition (temperature) where the oligomer-containing layer is introduced toward the inside of the concave portion formed in the surface of the wafer 200 by allowing the oligomer-containing layer to flow toward the inside of the concave portion so as to fill the concave portion with the oligomer-containing layer from the inside in the concave portion.

An example of a processing condition in the precursor gas supply is described as follows.

Processing temperature (first temperature): 0 to 150 degrees C., specifically 10 to 100 degrees C., more specifically 20 to 60 degrees C.

Processing pressure: 10 to 6,000 Pa, specifically 50 to 2,000 Pa

Precursor gas supply flow rate: 0.01 to 1 slm

Precursor gas supply time: 1 to 300 seconds

Inert gas supply flow rate (for each gas supply pipe): 0 to 10 slm, specifically 0.01 to 10 slm

In the present disclosure, the notation of a numerical range such as “0 to 150 degrees C.” means that the lower limit value and the upper limit value are included in the range. Therefore, for example, “0 to 150 degrees C.” means “0 degrees C. or higher and 150 degrees C. or lower.” The same applies to other numerical ranges. In the present disclosure, the processing temperature means the temperature of the wafer 200 or the internal temperature of the process chamber 201, and the processing pressure means the internal pressure of the process chamber 201. Further, the gas supply flow rate of 0 slm means a case where no gas is supplied. These apply equally to the following description.

An example of a processing condition in the first N- and H-containing gas supply is described as follows.

First N- and H-containing gas supply flow rate: 0.01 to 5 slm

First N- and H-containing gas supply time: 1 to 300 seconds

Other process conditions may be the same as the process conditions for precursor gas supply.

An example of a processing condition in the second N- and H-containing gas supply is described as follows.

Second N- and H-containing gas supply flow rate: 0.01 to 5 slm

Second N- and H-containing gas supply time: 1 to 300 seconds

Other process conditions may be the same as the process conditions for precursor gas supply.

An example of a processing condition in the first modifying gas supply when the modifying gas is thermally excited is described as follows.

Processing pressure: 70 to 10,000 Pa, specifically 1,000 to 10,000 Pa

Modifying gas supply flow rate: 0.01 to 10 slm

Modifying gas supply time: 1 to 300 seconds

Temperature of modifying gas: 100 to 600 degrees C., specifically 200 to 500 degrees C., more specifically 300 to 450 degrees C., still more specifically 300 to 400 degrees C.

Other process conditions may be the same as the process conditions for precursor gas supply. Note that the temperature of the modifying gas is higher than the temperature of the wafer 200. Further, it is desirable that the processing pressure in thermally exciting the modifying gas is higher than the processing pressure in each of the precursor gas supply, the first N- and H-containing gas supply, and the second N- and H-containing gas supply.

An example of a processing condition in the first modifying gas supply when the modifying gas is plasma-excited is described as follows.

Processing pressure: 1 to 100 Pa, specifically 10 to 80 Pa

Modifying gas supply flow rate: 0.01 to 10 slm

Modifying gas supply time: 1 to 300 seconds

Radio-frequency (RF) power: 100 to 1,000 W

Radio-frequency (RF) frequency: 13.5 MHz or 27 MHz

Other process conditions may be the same as the process conditions for precursor gas supply. Further, it is desirable that the processing pressure in plasma-exciting the modifying gas is lower than the processing pressure in each of the precursor gas supply, the first N- and H-containing gas supply, and the second N- and H-containing gas supply.

By performing the precursor gas supply, the first N- and H-containing gas supply, the second N- and H-containing gas supply, and the first modifying gas supply under the above-described process conditions, it is possible to form an oligomer-containing layer on the surface of the wafer 200 and in the concave portion of the wafer 200 by allowing an oligomer, which contains an element contained in at least one selected from the group of the precursor gas, the first N- and H-containing gas, and the second N- and H-containing gas, to be generated, grow, and flow on the surface of the wafer 200 and in the concave portion of the wafer 200. The oligomer refers to a polymer having a relatively low molecular weight (for example, a molecular weight of 10,000 or less) in which a relatively small amount of (for example, 10 to 100) monomers are bonded. When using, for example, an alkylhalosilane-based gas such as an alkylchlorosilane-based gas or the like, an amine-based gas, and a hydrogen nitride-based gas as the precursor gas, the first N- and H-containing gas, and the second N- and H-containing gas, respectively, the oligomer-containing layer is, for example, a layer containing various elements such as Si, Cl, and N or a substance represented by a chemical formula of CₓH₂ₓ₊₁ (where x is an integer of 1 to 3) such as CH₃ or C₂H₅.

Further, by performing the precursor gas supply, the first N- and H-containing gas supply, the second N- and H-containing gas supply, and the first modifying gas supply under the above-described process conditions, it is possible to remove and discharge excess components contained in the surface layer of the oligomer and inside the oligomer, such as an excess gas, impurities including Cl and the like, and reaction by-products (hereinafter also simply referred to as by-products), while promoting the growth and flow of the oligomer formed on the surface of the wafer 200 and in the concave portion of the wafer 200.

If the above-mentioned processing temperature is lower than 0 degrees C., the precursor gas supplied into the process chamber 201 tends to be liquefied, which may make it difficult to supply the precursor gas in a gaseous state to the wafer 200. In this case, a reaction for forming the above-mentioned oligomer-containing layer may be difficult to proceed, which may make it difficult to form the oligomer-containing layer on the surface of the wafer 200 and in the concave portion of the wafer 200. It is possible to solve this problem by setting the processing temperature to 0 degrees C. or higher. It is possible to sufficiently solve this problem by setting the processing temperature to 10 degrees C. or higher, and it is possible to more sufficiently solve this problem by setting the processing temperature to 20 degrees C. or higher.

If the processing temperature is higher than 150 degrees C., a catalytic action by the first N- and H-containing gas, which will be described later, is weakened, which may make it difficult to progress the reaction for forming the above-mentioned oligomer-containing layer. In this case, desorption of the oligomer generated on the surface of the wafer 200 and in the concave portion of the wafer 200 is predominant over growth of the oligomer, which may make it difficult to form the oligomer-containing layer on the surface of the wafer 200 and in the concave portion of the wafer 200. It is possible to solve this problem by setting the processing temperature to 150 degrees C. or lower. It is possible to sufficiently solve this problem by setting the processing temperature to 100 degrees C. or lower, and it is possible to more sufficiently solve this problem by setting the processing temperature to 60 degrees C. or lower.

For these reasons, it is desirable that the processing temperature is 0 degrees C. or higher and 150 degrees C. or lower, specifically 10 degrees C. or higher and 100 degrees C. or lower, more specifically 20 degrees C. or higher and 60 degrees C. or lower.

An example of a processing condition in the purging is described as follows.

Processing pressure: 10 to 6,000 Pa

Inert gas supply flow rate (for each gas supply pipe): 0.01 to 20 slm

Inert gas supply time: 1 to 300 seconds

Other process conditions may be the same as the process conditions for precursor gas supply.

By performing the purging under the above-described process conditions, it is possible to remove and discharge excess components contained in the oligomer, such as an excess gas, impurities including Cl and the like, and by-products, while promoting the flow of the oligomer formed on the surface of the wafer 200 and in the concave portion of the wafer 200.

### (Post-Treatment (PT))

After the oligomer-containing layer is formed on the surface of wafer 200 and in the concave portion of the wafer 200, the output of the heater 207 is adjusted so as to change the temperature of the wafer 200 to a second temperature equal to or higher than the above-mentioned first temperature, desirably to a second temperature higher than the above-mentioned first temperature.

After the temperature of the wafer 200 reaches the second temperature, a modifying gas is supplied to the wafer 200 in the process chamber 201. Specifically, the valve 243d is opened to allow the modifying gas to flow into the gas supply pipe 232d. The flow rate of the modifying gas is adjusted by the MFC 241d, and the modifying gas is supplied into the process chamber 201 via the nozzle 249b and is exhausted through the exhaust port 231a. In this operation, the modifying gas is supplied to the wafer 200. At this time, the valves 243e to 243g may be opened to allow an inert gas to be supplied into the process chamber 201 via the nozzles 249a to 249c, respectively. After a predetermined time has elapsed, the valve 243d is closed to stop the supply of the modifying gas into the process chamber 201. As the modifying gas, the same gas as the modifying gas used in step 4 may be used. That is, for example, at least one selected from the group of an inert gas, a N- and H-containing gas, and a H-containing gas may be used as the modifying gas. Further, before the temperature of the wafer 200 reaches the second temperature, for example, from a state where the temperature of the wafer 200 is the first temperature, the modifying gas may be supplied to the wafer 200 in the process chamber 201. In this case, the modifying gas is supplied to the wafers 200 even while the temperature of the wafers 200 is rising from the first temperature to the second temperature, which makes it possible to enhance the modifying effect to be described later. FIG. 4 shows an example in which an inert gas is supplied as the modifying gas in PT.

It is desirable that this step is performed under the process conditions that cause fluidity in the oligomer-containing layer formed on the surface of the wafer 200 and in the concave portion of the wafer 200. Further, it is desirable that this step is performed under the process conditions where excess components contained in the surface layer of the oligomer-containing layer and inside the oligomer-containing layer, such as an excess gas, impurities including Cl and the like, and by-products, are removed and discharged while promoting the flow of the oligomer-containing layer formed on the surface of the wafer 200 and in the concave portion of the wafer 200, to densify the oligomer-containing layer.

An example of a processing condition in PT is described as follows.

Processing temperature (second temperature): 100 to 1,000 degrees C., specifically 200 to 600 degrees C.

Processing pressure: 10 to 80,000 Pa, specifically 200 to 6,000 Pa

Processing time: 300 to 10,800 seconds

Modifying gas supply flow rate: 0.01 to 20 slm

By performing PT under the above-described process conditions, it is possible to modify the oligomer-containing layer formed on the surface of the wafer 200 and in the concave portion of the wafer 200. This makes it possible to form a silicon carbonitride film (SiCN film), which is a film containing Si, C, and N, as a film obtained by modifying the oligomer-containing layer, so as to fill the concave portion. Further, it is possible to discharge excess components contained in the oligomer-containing layer while promoting the flow of the oligomer-containing layer, to densify the oligomer-containing layer.

### (After-Purge and Returning to Atmospheric Pressure)

After the formation of the SiCN film is completed, an inert gas acting as a purge gas is supplied into the process chamber 201 from each of the nozzles 249a to 249c and is exhausted through the exhaust port 231a. Thus, the interior of the process chamber 201 is purged and a gas, reaction by-products, and the like remaining in the process chamber 201 are removed from the interior of the process chamber 201 (after-purge). After that, the internal atmosphere of the process chamber 201 is substituted with an inert gas (inert gas substitution) and the internal pressure of the process chamber 201 is returned to the atmospheric pressure (returning to atmospheric pressure).

### (Boat Unloading and Wafer Discharging)

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter close). The processed wafers 200 are unloaded from the reaction tube 203 and are then discharged from the boat 217 (wafer discharging).

### (3) Effects of the Present Embodiment

According to the present embodiment, one or more effects set forth below may be achieved.
(a) By forming the oligomer-containing layer at the above-mentioned first temperature and performing the PT at the second temperature equal to or higher than the first temperature, it is possible to improve the filling characteristics of the film formed in the concave portion. Further, by performing the PT at the second temperature higher than the first temperature, it is possible to further enhance the above effect.
(b) In the oligomer-containing layer formation, when the precursor gas exists alone, by performing the cycle a predetermined number of times under the condition where physical adsorption of the precursor gas is predominant over chemical adsorption of the precursor gas, the fluidity of the oligomer-containing layer can be increased, which makes it possible to the filling characteristics of the film formed in the concave portion.
(c) In the oligomer-containing layer formation, when the precursor gas exists alone, by performing the cycle a predetermined number of times under the condition where physical adsorption of the precursor gas is predominant over thermal decomposition of the precursor gas and chemical adsorption of the precursor gas, it is possible to increase the fluidity of the oligomer-containing layer. As a result, it is possible to improve the filling characteristics of the film formed in the concave portion.
(d) In the oligomer-containing layer formation, when the precursor gas exists alone, by performing the cycle a predetermined number of times under the condition where physical adsorption of the precursor gas is predominant over chemical adsorption of the precursor gas without thermal decomposition of the precursor gas, it is possible to increase the fluidity of the oligomer-containing layer. As a result, it is possible to improve the filling characteristics of the film formed in the concave portion.
(e) In the oligomer-containing layer formation, by performing the cycle a predetermined number of times under the condition that causes to generate the fluidity in the oligomer-containing layer, it is possible to improve the filling characteristics of the film formed in the concave portion.
(f) In the oligomer-containing layer formation, by performing the cycle a predetermined number of times under the condition where the oligomer-containing layer is introduced toward the inside in the concave portion by allowing the oligomer-containing layer to flow toward the inside in the concave portion to fill the concave portion with the oligomer-containing layer from the inside of the concave portion, it is possible to improve the filling characteristics of the film formed in the concave portion.
(g) By using the alkylchlorosilane-based gas as the precursor gas, it is possible to make the oligomer-containing layer contain Si, C, and Cl.
(h) By differentiating the molecular structure of the first N- and H-containing gas from the molecular structure of the second N- and H-containing gas, each gas can play a different role. For example, as in the present embodiment, by using an amine-based gas as the first N- and H-containing gas, this gas is caused to act as a catalyst so as to make it possible to activate the precursor gas physically adsorbed on the surface of the wafer 200 by the precursor gas supply. Further, by using a hydrogen nitride-based gas as the second N- and H-containing gas, this gas is caused to act as a N source so as to make it possible to contain N in the oligomer-containing layer.
(i) In the oligomer-containing layer formation, by performing the cycle a predetermined number of times, the cycle that non-simultaneously performs the precursor gas supply, the first N- and H-containing gas supply, the second N- and H-containing gas supply, and the first modifying gas supply, it is possible to improve the filling characteristics of the film formed in the concave portion.

It is thought that this is due to the fact that the precursor gas and the first N- and H-containing gas acting as a catalyst are supplied separately at different timings to control the variation in the state of mixing between the precursor gas and the first N- and H-containing gas. According to the present embodiment, it is possible to improve the variation in growth of each oligomer generated in a plurality of places on the surface of the wafer 200 and in the concave portion of the wafer 200 and suppress the variation in growth in a fine region, thereby making it possible to suppress the occurrence of voids, seams, and the like in the concave portion. As a result, it is possible to improve the filling characteristics of the film formed in the concave portion.

That is, void-free and seamless filling becomes possible.
(j) In the oligomer-containing layer formation, by performing the purging at a predetermined timing, it is possible to discharge excess components (impurities, by-products, etc.) contained in the surface layer of the oligomer and inside the oligomer while promoting the flow of the oligomer formed on the surface of the wafer 200 and in the concave portion of the wafer 200. As a result, it is possible to improve the filling characteristics of the film formed in the concave portion. Further, it is possible to reduce the impurity concentration of the film formed so as to fill the concave portion, thereby making it possible to improve the wet etching resistance of the film formed in the concave portion. As a result, it is possible to improve the film quality and characteristics of the film formed in the concave portion.
(k) In the oligomer-containing layer formation, by performing the first modifying gas supply at a predetermined timing, it is possible to discharge excess components (impurities, by-products, etc.) contained in the surface layer of the oligomer and inside the oligomer while promoting the growth and flow of the oligomer formed on the surface of the wafer 200 and in the concave portion of the wafer 200. As a result, it is possible to improve the filling characteristics of the film formed in the concave portion. Further, it is possible to reduce the impurity concentration of the film formed so as to be filled in the concave portion, thereby making it possible to improve the wet etching resistance of the film formed in the concave portion. As a result, it is possible to improve the film quality and characteristics of the film formed in the concave portion.

Further, by using a gas heated to a temperature higher than the temperature of the wafer 200 as the first modifying gas, it is possible to impart high thermal energy to the oligomer. This makes it possible to enhance the reactivity when removing excess components (impurities, by-products, etc.) contained in the surface layer of the oligomer and inside the oligomer, that is, the effect of removing excess components from the surface layer of the oligomer and the inside of the oligomer. Further, in this case, by setting the processing pressure in the first modifying gas supply to be higher than the processing pressure in each of the precursor gas supply, the first N- and H-containing gas supply, and the second N- and H-containing gas supply, the gas density of the first modifying gas in the process chamber 201 can be increased, which makes it possible to increase the collision frequency of the gas with the surface layer of the oligomer. This makes it possible to further enhance the reactivity when removing excess components contained in the oligomer surface layer and inside the oligomer, that is, the effect of removing excess components from the surface layer of the oligomer and the inside of the oligomer.

Further, by using a gas excited into a plasma state as the first modifying gas, it is possible to impart plasma energy to the oligomer. This makes it possible to enhance the reactivity when removing excess components (impurities, by-products, etc.) contained in the surface layer of the oligomer and inside the oligomer, that is, the effect of removing excess components from the surface layer of the oligomer and the inside of the oligomer. In this case, by setting the processing pressure in the first modifying gas supply to be lower than the processing pressure in each of the precursor gas supply, the first N- and H-containing gas supply, and the second N- and H-containing gas supply, it is possible to suppress deactivation of active species caused by the plasma-excitation of the modifying gas. This makes it possible to further enhance the reactivity when removing excess components contained in the oligomer surface layer and inside the oligomer, that is, the effect of removing excess components from the surface layer of the oligomer and the inside of the oligomer.
(l) By performing PT under the condition that causes the fluidity in the oligomer-containing layer, it is possible to improve the filling characteristics of the film formed in the concave portion. Further, in the PT, by discharging excess components contained in the oligomer-containing layer while promoting the flow of the oligomer-containing layer, to densify the oligomer-containing layer, it is possible to improve the filling characteristics of the film formed in the concave portion. Further, it is possible to reduce the impurity concentration of the film formed so as to be filled in the concave portion and further to increase the film density. This makes it possible to improve the wet etching resistance of the film formed in the concave portion. As a result, it is possible to improve the film quality and characteristics of the film formed in the concave portion.
(m) In the PT, by supplying the modifying gas to the wafer 200, it is possible to promote the flow of the oligomer-containing layer, thereby improving the filling characteristics of the film formed in the concave portion. Further, it is possible to reduce the impurity concentration of the film formed so as to be filled in the concave portion and further to increase the film density. This makes it possible to improve the wet etching resistance of the film formed in the concave portion. As a result, it is possible to improve the film quality and characteristics of the film formed in the concave portion. Further, it is possible to further enhance these effects by using a N- and H-containing gas or a H-containing gas as the modifying gas rather than by using an inert gas as the modifying gas.
(n) The above-described effects can be similarly obtained even when using the above-mentioned various precursor gases, the above-mentioned various first N- and H-containing gases, the above-mentioned various second N- and H-containing gases, the above-mentioned various inert gases, and the above-mentioned various first modifying gases in the oligomer-containing layer formation. Further, the above-described effects can be similarly obtained even when changing the order of gas supply in the cycle. Further, the above-described effects can be similarly obtained even when using the above-mentioned various modifying gases in the PT.

### Second Embodiment of the Present Disclosure

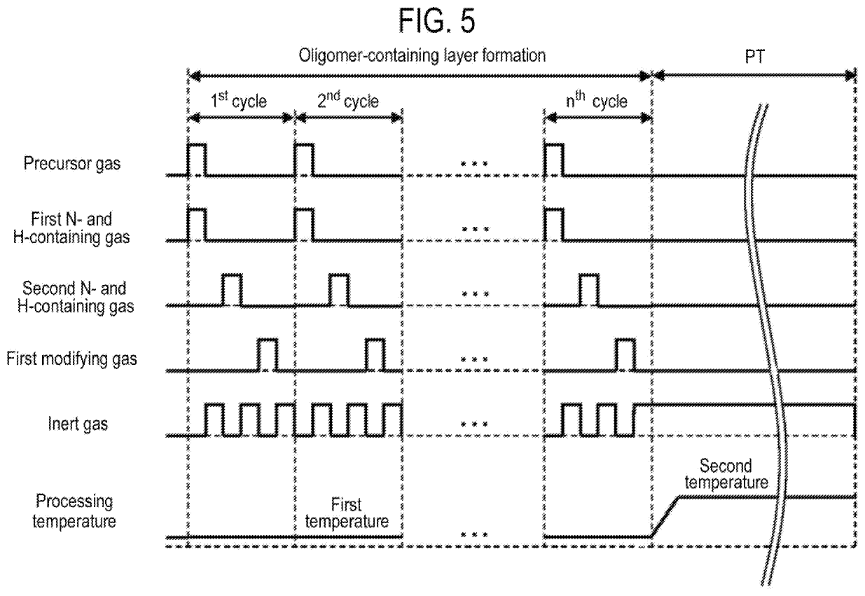

Next, a second embodiment of the present disclosure will be described mainly with reference to FIG. 5.

As in FIG. 5 and the processing sequence shown below, the oligomer-containing layer formation may include performing a cycle a predetermined number of times (n times, where n is an integer of 1 or more), the cycle including non-simultaneously performing:
a step of simultaneously performing a step of supplying a precursor gas to a wafer 200 and a step of supplying a first N- and H-containing gas to the wafer 200;
a step of supplying a second N- and H-containing gas to the wafer 200; and a step of supplying a first modifying gas to the wafer 200.

FIG. 5 and the processing sequence shown below show an example of performing the same PT as in the first embodiment. Further, FIG. 5 shows an example in which an inert gas is supplied as the modifying gas in the PT.

(Precursor gas+First N- and H-containing gas→Second N- and H-containing gas→First modifying gas)×n→PT

This embodiment also obtains the same effects as the above-described first embodiment. Further, in this embodiment, since the precursor gas and the first N- and H-containing gas are simultaneously supplied, it is possible to improve a cycle rate, thereby increasing the productivity of substrate processing.

### Third Embodiment of the Present Disclosure

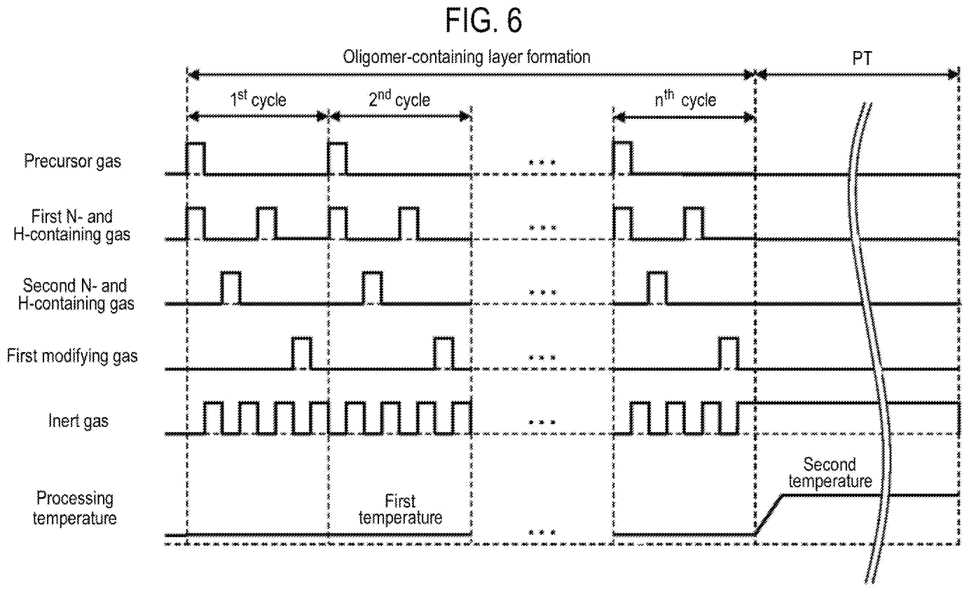

Next, a third embodiment of the present disclosure will be described mainly with reference to FIG. 6.

As in FIG. 6 and the processing sequence shown below, the oligomer-containing layer formation may include performing a cycle a predetermined number of times (n times, where n is an integer of 1 or more), the cycle including non-simultaneously performing:
a step of simultaneously performing a step of supplying a precursor gas to a wafer 200 and a step of supplying a first N- and H-containing gas to the wafer 200;
a step of supplying a second N- and H-containing gas to the wafer 200;
a step of supplying the first N- and H-containing gas to the wafer 200; and
a step of supplying a first modifying gas to the wafer 200.

FIG. 6 and the processing sequence shown below show an example of performing the same PT as in the first embodiment. Further, FIG. 6 shows an example in which an inert gas is supplied as the modifying gas in the PT.

(Precursor gas+First N- and H-containing gas→Second N- and H-containing gas→First N- and H-containing gas→First modifying gas)×n→PT

This embodiment also obtains the same effects as the above-described first embodiment. Further, in this embodiment, the first N- and H-containing gas, which flows at the first time in the cycle, acts as a catalyst to make it possible to activate the precursor gas. Further, it is possible to make the first N- and H-containing gas, which flows at the second time in the cycle, act as a gas for removing by-products and the like generated during the oligomer-containing layer formation, that is, as a reactive purge gas. The process conditions for supplying these first N- and H-containing gases may be the same as the process conditions for supplying the above-described first N- and H-containing gas.

### Fourth Embodiment of the Present Disclosure

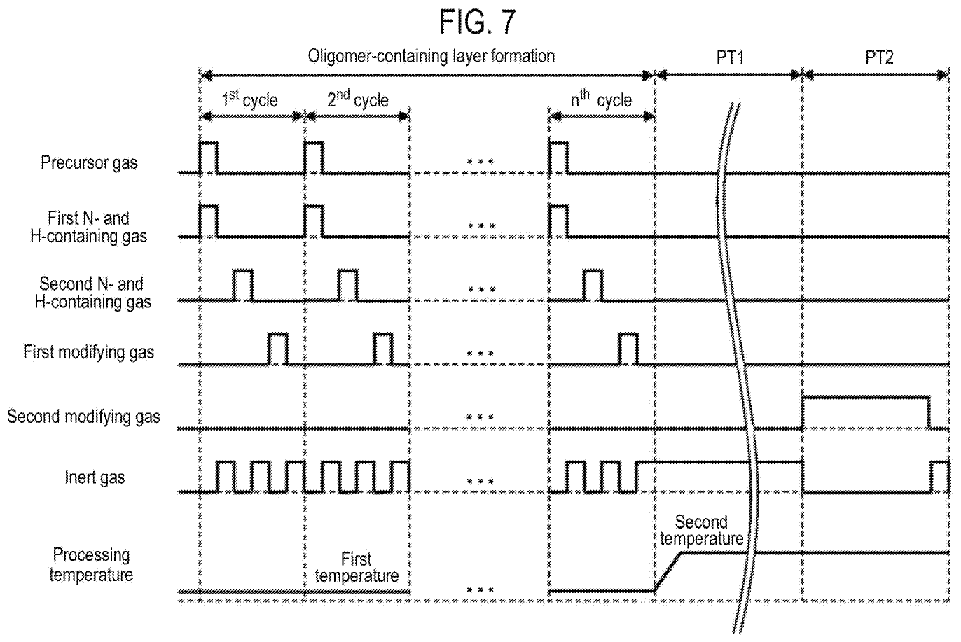

Next, a fourth embodiment of the present disclosure will be described mainly with reference to FIG. 7.

As in FIG. 7 and the processing sequence shown below, the PT may include performing:
a step (PT1) of forming a film, which is obtained by modifying the oligomer-containing layer, by performing a thermal treatment to the oligomer-containing layer, which is formed on the surface of the wafer 200 and in concave portion of the wafer 200, at the second temperature equal to or higher than the first temperature, to modify the oligomer-containing layer formed on the surface of the wafer 200 and in the concave portion of the wafer 200 so as to be filled in the concave portion; and
a step (PT2) of supplying a second modifying gas, which includes at least one selected from the group of a gas heated to a temperature higher than the temperature of the wafer 200 and a gas excited into a plasma state, to the film obtained by modifying the oligomer-containing layer formed so as to be filled in the concave portion.

FIG. 7 and the processing sequence shown below show an example of forming the same oligomer-containing layer as in the second embodiment. Further, FIG. 7 shows an example in which an inert gas is supplied as the modifying gas in the PT1.

(Precursor gas+First N- and H-containing gas→Second N- and H-containing gas→First modifying gas)×n→PT1→PT2

The process conditions in the PT1 may be the same as the process conditions in the PT of the above-described first embodiment. The process conditions in the PT2 may be the same as the process conditions in the first modifying gas supply of the above-described first embodiment except for the processing temperature, modifying gas temperature, and modifying gas supply time. The processing temperature and modifying gas temperature in the PT2 may be the same as the processing temperature (second temperature) in the PT1. However, the modifying gas temperature in the PT2 needs to be higher than the processing temperature in the PT2. The modifying gas temperature in the PT2 and the processing temperature in the PT2 are adjusted within a range of the processing temperature (second temperature) in the PT1. Further, it is desirable that the modifying gas supply time in the PT2 is longer than the modifying gas supply time in the first modifying gas supply.

Further, in this embodiment, the same oligomer-containing layer as in the first embodiment and the third embodiment may be formed instead of forming the same oligomer-containing layer as in the second embodiment. Further, in FIG. 7, in the PT1, a N- and H-containing gas or a H-containing gas may be supplied instead of supplying an inert gas as the modifying gas.

This embodiment also obtains the same effects as the above-described first embodiment. Further, in this embodiment, since the PT2 is performed after the PT1 is performed, the film obtained by modifying the oligomer-containing layer formed so as to be filled in the concave portion in the PT1 can be further modified in the PT2. That is, in the PT2, it is possible to remove and discharge excess components, which are contained in the film obtained by modifying the oligomer-containing layer formed so as to be filled in the concave portion in the PT1, such as an excess gas, impurities including Cl and the like, by-products, etc., which could not be completely removed in the oligomer-containing layer formation and in the PT1. This makes it possible to improve the wet etching resistance of the film formed in the concave portion. As a result, it is possible to improve the film quality and characteristics of the film formed in the concave portion.

Further, in this embodiment, a modifying process (PT1) performed under the second temperature equal to or higher than the first temperature and a modifying process (PT2) using the first modifying gas may be alternately repeated a plurality of times. By alternately repeating the PT1 and the PT2 a plurality of times, it is possible to further enhance the above-described modifying effect of the PT1 and modifying effect of the PT2.

### Fifth Embodiment of the Present Disclosure

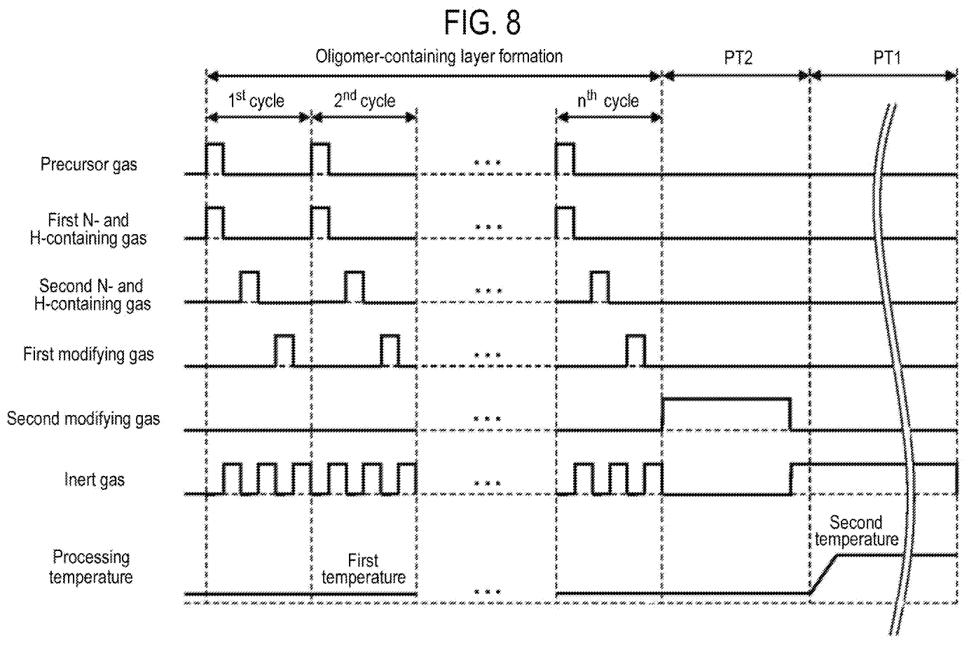

Next, a fifth embodiment of the present disclosure will be described mainly with reference to FIG. 8.

As in FIG. 8 and the processing sequence shown below, the PT may include performing:
a step (PT2) of supplying a second modifying gas, which includes at least one selected from the group of a gas heated to a temperature higher than the temperature of the wafer 200 and a gas excited into a plasma state, to the oligomer-containing layer formed on the surface of the wafer 200 and in the concave portion of the wafer 200; and
a step (PT1) of forming a film, which is obtained by modifying the oligomer-containing layer, by performing a thermal treatment to the oligomer-containing layer, which is formed on the surface of the wafer 200 and in concave portion of the wafer 200 and modified by the PT2, at the second temperature equal to or higher than the first temperature, to further modify the oligomer-containing layer formed on the surface of the wafer 200 and in the concave portion of the wafer 200 and modified by the PT2 to so as to be filled in the concave portion.

FIG. 8 and the processing sequence shown below show an example of forming the same oligomer-containing layer as in the second embodiment. Further, FIG. 8 shows an example in which an inert gas is supplied as the modifying gas in the PT1.

(Precursor gas+First N- and H-containing gas→Second N- and H-containing gas→First modifying gas)×n→PT2→PT1

The process conditions in the PT2 may be the same as the process conditions in the first modifying gas supply of the above-described first embodiment except for the modifying gas supply time. Further, it is desirable that the modifying gas supply time in the PT2 is longer than the modifying gas supply time in the first modifying gas supply. The process conditions in the PT1 may be the same as the process conditions in the PT of the above-described first embodiment.

Further, in this embodiment, the same oligomer-containing layer as in the first embodiment and the third embodiment may be formed instead of forming the same oligomer-containing layer as in the second embodiment. Further, in FIG. 8, in the PT1, a N- and H-containing gas or a H-containing gas may be supplied instead of supplying an inert gas as the modifying gas.

This embodiment also obtains the same effects as the above-described first embodiment. Further, in this embodiment, since the PT1 is performed after the PT2 is performed, the oligomer-containing layer modified in the PT2 can be further modified in the PT1. That is, in the PT1, it is possible to form a film obtained by modifying the oligomer-containing layer so as to be filled in the concave portion while removing and discharging excess components, which are contained in the oligomer-containing layer formed on the surface of the wafer 200 and in the concave portion of the wafer 200 and modified in the PT2, such as an excess gas, impurities including Cl and the like, by-products, etc., which could not be completely removed in the oligomer-containing layer formation and in the PT2. This makes it possible to improve the wet etching resistance of the film formed in the concave portion. As a result, it is possible to improve the film quality and characteristics of the film formed in the concave portion.

Further, in this embodiment, a modifying process (PT2) using the first modifying gas and a modifying process (PT1), which is performed at the second temperature equal to or higher than the first temperature, may be alternately repeated a plurality of times. By alternately repeating the PT2 and the PT1 a plurality of times, it is possible to further enhance the above-described modifying effect of the PT2 and modifying effect of the PT1.

### Other Embodiments of the Present Disclosure

Various embodiments of the present disclosure have been specifically described above. However, the present disclosure is not limited to the above-described embodiments, and can be modified in various ways without departing from the gist of the present disclosure.

For example, in at least one selected from the group of the PT, the PT1, and the PT2, an oxygen (O)-containing gas may be supplied as the modifying gas instead of supplying an inert gas, a N- and H-containing gas, and a H-containing gas, or together at least one of these gases. As the O-containing gas, an O-containing gas such as a H₂O gas, that is, an O- and H-containing gas, may be used, or an O-containing gas such as an O₂ gas may be used.

The process conditions in the PT in this case may be the same as the process conditions in the PT of the above-described first embodiment. Further, the process conditions in the PT1 and the PT2 in this case may be the same as the process conditions in the PT1 and the PT2 of the above-described fourth embodiment or fifth embodiment, respectively. Even in this case, the same effects as in the above-described first embodiment can be obtained.

Further, it is possible to increase the fluidity of the oligomer-containing layer and improve the filling characteristics of the film formed in the concave portion more in the case of performing the PT, the PT1, and the PT2 under a H-containing gas atmosphere and in the case of performing the PT, the PT1, and the PT2 under a N- and H-containing gas atmosphere than in the case of performing the PT, the PT1, and the PT2 under an inert gas atmosphere. Further, it is possible to reduce the impurity concentration of the film formed in the concave portion, increase the film density, and improve the wet etching resistance more in the case of performing the PT, the PT1, and the PT2 under a H-containing gas atmosphere and in the case of performing the PT, the PT1, and the PT2 under a N- and H-containing gas atmosphere than in the case of performing the PT, the PT1, and the PT2 under an inert gas atmosphere. As a result, it is possible to improve the film quality and characteristics of the film formed in the concave portion. Further, these effects can be enhanced more in the case of performing the PT, the PT1, and the PT2 under the N- and H-containing gas atmosphere than the case of performing the PT, the PT1, and the PT2 under the H-containing gas atmosphere. Further, in the case of performing the PT, the PT1, and the PT2 under an O-containing gas atmosphere, it is possible to contain O in the film obtained by modifying the oligomer-containing layer, which makes it possible to make this film a silicon oxynitride carbide film (SiOCN film) which is a film containing Si, O, C, and N.

Further, for example, the PT and PT1 may include non-simultaneously performing:
a step (PTX) of supplying at least one selected from the group of an inert gas, a N-containing gas, a H-containing gas, and a N- and H-containing gas to the wafer 200 on which the oligomer-containing layer is formed; and
a step (PTO) of supplying at least one selected from the group of an O-containing gas and an O- and H-containing gas to the wafer 200 on which the oligomer-containing layer is formed.

The process conditions for each of the PTX and the PTO may be the same as the process conditions for the PT of the above-described first embodiment. Even in this case, the same effects as in the above-described first embodiment can be obtained.

Further, in the case of performing the PTO under an O-containing gas atmosphere, O is contained in the film obtained by modifying the oligomer-containing layer, which makes it possible to make this film a SiOCN film. Further, by using an O- and H-containing gas such as a H₂O gas with relatively low oxidizing power, as the O-containing gas, it is possible to suppress desorption of C from the SiOCN film obtained by modifying the oligomer-containing layer. Further, by performing the PTX and the PTO in this order, it is possible to suppress desorption of C from the SiOCN film obtained by modifying the oligomer-containing layer.

Further, for example, as in the processing sequence shown below, a step (O-containing gas supply) of supplying an O-containing gas to the wafer 200 may be further performed in the oligomer-containing layer formation. Further, an O-containing gas may be supplied as the modifying gas in the first modifying gas supply. In these cases, in addition to obtaining the same effects as the above-described first embodiment, it is possible to allow O to be contained in the oligomer-containing layer, and as a result, it is possible to form a SiOCN film so as to be filled in the concave portion. In the oligomer-containing layer formation, the process conditions for further performing the step of supplying the O-containing gas to the wafer 200 may be the same as the process conditions for the second N- and H-containing gas supply in the above-described first embodiment. Further, in the first modifying gas supply, the process conditions for supplying the O-containing gas as the modifying gas may be the same as the process conditions for the first modifying gas supply of the above-described first embodiment.

(Precursor gas→First N- and H-containing gas→Second N- and H-containing gas→O-containing gas→First modifying gas)×n→PT

(Precursor gas+First N- and H-containing gas→Second N- and H-containing gas→O-containing gas→First modifying gas)×n→PT

(Precursor gas+First N- and H-containing gas→Second N- and H-containing gas→First N- and H-containing gas→O-containing gas→First modifying gas)×n→PT

Further, for example, the first embodiment and a part of the third embodiment may be combined as in the processing sequence shown below.

(Precursor gas→First N- and H-containing gas→Second N- and H-containing gas→First N- and H-containing gas→First modifying gas)×n→PT

According to this processing sequence, it is possible to obtain both the effect obtained by the first embodiment and the effect obtained by the part of the third embodiment.

Further, in the oligomer-containing layer formation of the first embodiment, the second embodiment, the third embodiment, and the above-described other embodiments, the supply order of gas may be changed as in the processing sequence shown below. In the following, for the sake of convenience, the notation of PT is omitted, and only the processing sequence for the oligomer-containing layer formation is extracted and shown. Further, for the sake of convenience, the supply order of each gas in the oligomer-containing layer formation of the first embodiment, the second embodiment, the third embodiment, and the above-described other embodiments is also shown.

### <Variation of Supply Order of Each Gas in Oligomer-containing Layer Formation of First Embodiment>

(Precursor gas→First N- and H-containing gas→Second N- and H-containing gas→First modifying gas)×n

(Precursor gas→First N- and H-containing gas→First modifying gas→Second N- and H-containing gas)×n

### <Variation of Supply Order of Each Gas in Oligomer-Containing Layer Formation of Second Embodiment>

(Precursor gas+First N- and H-containing gas→Second N- and H-containing gas→First modifying gas)×n

(Precursor gas+First N- and H-containing gas→First modifying gas→Second N- and H-containing gas)×n

### <Variation of Supply Order of Each Gas in Oligomer-Containing Layer Formation of Third Embodiment>

(Precursor gas+First N- and H-containing gas→Second N- and H-containing gas→First N- and H-containing gas→First modifying gas)×n

(Precursor gas+First N- and H-containing gas→First modifying gas→Second N- and H-containing gas→First N- and H-containing gas)×n

(Precursor gas+First N- and H-containing gas→Second N- and H-containing gas→First modifying gas→First N- and H-containing gas)×n

### <Variation of Supply Order of Each Gas in Oligomer-Containing Layer Formation of Above-Described Other Embodiment>

(Precursor gas→First N- and H-containing gas→Second N- and H-containing gas→First N- and H-containing gas→First modifying gas)×n

(Precursor gas→First N- and H-containing gas→First modifying gas→Second N- and H-containing gas→First N- and H-containing gas)×n

(Precursor gas→First N- and H-containing gas→Second N- and H-containing gas→First modifying gas→First N- and H-containing gas)×n

Like these, by changing the supply order of each gas in the oligomer-containing layer formation, a timing of modifying the oligomer by the first modifying gas can be adjusted. In other words, the state of the oligomer to be modified by the first modifying gas can be changed and adjusted. As a result, the modifying reaction by the first modifying gas can be finely adjusted according to a degree of growth and a degree of fluidity of the oligomer, which makes it possible to optimize the modifying effect. Further, by adjusting the timing of modifying the oligomer, it is possible to control the composition ratio of the finally formed film.

In the above-described embodiments, an example has been described in which the oligomer-containing layer formation and the PT (PT1, PT2) are performed in the same process chamber 201 (in-situ). However, the present disclosure is not limited to such embodiments. For example, the oligomer-containing layer formation and the PT (PT1, PT2) may be performed in separate process chambers (ex-situ). Even in this case, the same effects as those in the above-described embodiments can be obtained. In the various cases described above, if these steps are performed in-situ, the wafers 200 are not exposed to the atmosphere during the process, and can be processed consistently while the wafers 200 are kept under vacuum, which makes it possible to perform stable substrate processing. Further, if these steps are performed ex-situ, the internal temperature of each process chamber can be set in advance to, for example, the processing temperature in each step or a temperature close thereto, which can shorten the time required for temperature adjustment, thereby improving the production efficiency.

So far, an example has been described in which the SiCN film or the SiOCN film is formed so as to be filled in the concave portion formed on the surface of the wafer 200, but the present disclosure is not limited to these examples. That is, the present disclosure can also be suitably applied to a case where gas species of the precursor gas, the first N- and H-containing gas, the second N- and H-containing gas, and the modifying gas are arbitrarily combined to form a silicon nitride film (SiN film), a silicon oxide film (SiO film), a silicon oxycarbide film (SiOC film), and a silicon film (Si film) so as to be filled in the concave portion formed on the surface of the wafer 200. Also in this case, the same effects as those in the above-described embodiments can be obtained. Further, the present disclosure can be suitably applied to a case of forming, for example, STI (Shallow Trench Isolation), PMD (Pre-Metal dielectric), IMD (Inter-metal dielectric), ILD (Inter-layer dielectric), Gate Cut fill, or the like.

Recipes used in substrate processing may be prepared individually according to the processing contents and may be stored in the memory 121c via a telecommunication line or the external memory 123. Moreover, at the beginning of each process, the CPU 121a may properly select an appropriate recipe from the recipes stored in the memory 121c according to the substrate processing contents. Thus, it is desirable for a single substrate processing apparatus to form films of various kinds, composition ratios, qualities, and thicknesses with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the existing substrate processing apparatus may be directly modified by operating the input/output device 122 of the substrate processing apparatus.

An example in which a film is formed using a batch-type substrate processing apparatus capable of processing a plurality of substrates at a time has been described in the above-described embodiments. The present disclosure is not limited to the above-described embodiments, but may be suitably applied, for example, to a case where a film is formed using a single-wafer type substrate processing apparatus capable of processing a single substrate or several substrates at a time. In addition, an example in which a film is formed using a substrate processing apparatus provided with a hot-wall-type process furnace has been described in the above-described embodiments. The present disclosure is not limited to the above-described embodiments, but may be suitably applied to a case where a film is formed using a substrate processing apparatus provided with a cold-wall-type process furnace.

Even in the case of using these substrate processing apparatuses, film formation may be performed according to the same sequence and process conditions as those in the above-described embodiments and modifications, and the same effects as the above-described embodiments and modifications are achieved.

The above-described embodiments and modifications may be used in proper combination. The processing procedures and process conditions used in this case may be the same as, for example, the processing procedures and process conditions in the above-described embodiments.

According to the present disclosure in some embodiments, it is possible to improve the properties of a film formed so as to be filled in a concave portion formed on the surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
(a) forming an oligomer-containing layer on a surface of a substrate and in a concave portion of the substrate by allowing an oligomer, which contains an element contained in at least one selected from the group of a precursor gas, a first nitrogen- and hydrogen-containing gas, and a second nitrogen- and hydrogen-containing gas, to be generated, grow, and flow on the surface of the substrate and in the concave portion of the substrate by performing a cycle a predetermined number of times at a first temperature, the cycle including:
supplying the precursor gas to the substrate provided with the concave portion in the surface of the substrate;
supplying the first nitrogen- and hydrogen-containing gas to the substrate;
supplying the second nitrogen- and hydrogen-containing gas to the substrate; and
supplying a first modifying gas, which includes at least one selected from the group of a gas heated to a temperature higher than a temperature of the substrate and a gas excited into a plasma state, to the substrate; and
(b) forming a film, which is obtained by modifying the oligomer-containing layer, by performing a thermal treatment to the substrate, which has the oligomer-containing layer formed on the surface of the substrate and in the concave portion of the substrate, at a second temperature equal to or higher than the first temperature to modify the oligomer-containing layer formed on the surface of the substrate and in the concave portion of the substrate so as to be filled in the concave portion.

2. The processing method of claim 1, wherein the cycle in (a) includes non-simultaneously performing:
supplying the precursor gas to the substrate;
supplying the first nitrogen- and hydrogen-containing gas to the substrate;
supplying the second nitrogen- and hydrogen-containing gas to the substrate; and
supplying the first modifying gas.

3. The processing method of claim 1, wherein the cycle in (a) includes sequentially performing:
supplying the precursor gas to the substrate;
supplying the first nitrogen- and hydrogen-containing gas to the substrate;
supplying the second nitrogen- and hydrogen-containing gas to the substrate; and
supplying the first modifying gas.

4. The processing method of claim 1, wherein the cycle in (a) includes sequentially performing:
supplying the precursor gas to the substrate;
supplying the first nitrogen- and hydrogen-containing gas to the substrate;
supplying the first modifying gas; and
supplying the second nitrogen- and hydrogen-containing gas to the substrate.

5. The processing method of claim 1, wherein the cycle in (a) includes non-simultaneously performing:
simultaneously performing supplying the precursor gas to the substrate and supplying the first nitrogen- and hydrogen-containing gas to the substrate;
supplying the second nitrogen- and hydrogen-containing gas to the substrate; and
supplying the first modifying gas to the substrate.

6. The processing method of claim 1, wherein the cycle in (a) includes sequentially performing:
simultaneously performing supplying the precursor gas to the substrate and supplying the first nitrogen- and hydrogen-containing gas to the substrate;
supplying the second nitrogen- and hydrogen-containing gas to the substrate; and
supplying the first modifying gas to the substrate.

7. The processing method of claim 1, wherein the cycle in (a) includes sequentially performing:
simultaneously performing supplying the precursor gas to the substrate and supplying the first nitrogen- and hydrogen-containing gas to the substrate;
supplying the first modifying gas to the substrate; and
supplying the second nitrogen- and hydrogen-containing gas to the substrate.

8. The processing method of claim 1, wherein the cycle in (a) includes non-simultaneously performing:
simultaneously performing supplying the precursor gas to the substrate and supplying the first nitrogen- and hydrogen-containing gas to the substrate;
supplying the second nitrogen- and hydrogen-containing gas to the substrate;
supplying the first nitrogen- and hydrogen-containing gas to the substrate; and
supplying the first modifying gas.

9. The processing method of claim 1, wherein the cycle in (a) includes sequentially performing:
simultaneously performing supplying the precursor gas to the substrate and supplying the first nitrogen- and hydrogen-containing gas to the substrate;
supplying the second nitrogen- and hydrogen-containing gas to the substrate;
supplying the first nitrogen- and hydrogen-containing gas to the substrate; and
supplying the first modifying gas.

10. The processing method of claim 1, wherein the cycle in (a) includes sequentially performing:
simultaneously performing supplying the precursor gas to the substrate and supplying the first nitrogen- and hydrogen-containing gas to the substrate;
supplying the first modifying gas;
supplying the second nitrogen- and hydrogen-containing gas to the substrate; and
supplying the first nitrogen- and hydrogen-containing gas to the substrate.

11. The processing method of claim 1, wherein the cycle in (a) includes sequentially performing:
simultaneously performing supplying the precursor gas to the substrate and supplying the first nitrogen- and hydrogen-containing gas to the substrate;
supplying the second nitrogen- and hydrogen-containing gas to the substrate;
supplying the first modifying gas; and
supplying the first nitrogen- and hydrogen-containing gas to the substrate.

12. The processing method of claim 1, further comprising (c) supplying a second modifying gas, which contains at least one selected from the group of a gas heated to a temperature higher than the temperature of the substrate and a gas excited into a plasma state, to at least one selected from the group of the oligomer-containing layer, which is formed on the surface of the substrate and in the concave portion of the substrate, and the film formed so as to be filled in the concave portion.

13. The processing method of claim 12, wherein after performing (a), (b) and (c) are alternately repeated.

14. The processing method of claim 1, wherein in at least one selected from the group of (a) and (b), an oxygen-containing gas is supplied to the substrate.

15. The processing method of claim 1, wherein the precursor gas does not contain an amino group and contains halogen.

16. The processing method of claim 1, wherein the precursor gas contains a silicon-to-silicon chemical bond.

17. The processing method of claim 1, wherein the precursor gas contains silicon and halogen, or contains silicon, halogen, and carbon.

18. The processing method of claim 1, wherein the first nitrogen- and hydrogen-containing gas and the second nitrogen- and hydrogen-containing gas have different molecular structures from each other.

19. The processing method of claim 1, wherein the first modifying gas is a gas obtained by heating at least one selected from the group of an inert gas, a nitrogen- and hydrogen-containing gas, a hydrogen-containing gas, and an oxygen-containing gas to a temperature higher than the temperature of the substrate and a gas obtained by exciting the at least one selected from the group of the inert gas, the nitrogen- and hydrogen-containing gas, the hydrogen-containing gas, and the oxygen-containing gas into a plasma state.

20. A method of manufacturing a semiconductor device, comprising:
(a) forming an oligomer-containing layer on a surface of a substrate and in a concave portion of the substrate by allowing an oligomer, which contains an element contained in at least one selected from the group of a precursor gas, a first nitrogen- and hydrogen-containing gas, and a second nitrogen- and hydrogen-containing gas, to be generated, grow, and flow by performing a cycle a predetermined number of times at a first temperature, the cycle including:
supplying the precursor gas to the substrate provided with the concave portion in the surface of the substrate;
supplying the first nitrogen- and hydrogen-containing gas to the substrate;
supplying the second nitrogen- and hydrogen-containing gas to the substrate; and
supplying a first modifying gas, which includes at least one selected from the group of a gas heated to a temperature higher than a temperature of the substrate and a gas excited into a plasma state, to the substrate; and
(b) forming a film, which is obtained by modifying the oligomer-containing layer, by performing a thermal treatment to the substrate, which has the oligomer-containing layer formed on the surface of the substrate and in the concave portion of the substrate, at a second temperature equal to or higher than the first temperature to modify the oligomer-containing layer formed on the surface of the substrate and in the concave portion of the substrate so as to be filled in the concave portion.

21. A processing apparatus comprising:
a precursor gas supply system configured to supply a precursor gas to a substrate;
a first nitrogen- and hydrogen-containing gas supply system configured to supply a first nitrogen- and hydrogen-containing gas to the substrate;
a second nitrogen- and hydrogen-containing gas supply system configured to supply a second nitrogen- and hydrogen-containing gas to the substrate;
a first modifying gas supply system configured to supply a first modifying gas, which includes at least one selected from the group of a gas heated to a temperature higher than a temperature of the substrate and a gas excited into a plasma state, to the substrate;
a heater configured to heat the substrate; and
a controller configured to be capable of controlling the precursor gas supply system, the first nitrogen- and hydrogen-containing gas supply system, the second nitrogen- and hydrogen-containing gas supply system, the first modifying gas supply system, and the heater so as to perform a process including:
(a) forming an oligomer-containing layer on a surface of the substrate and in a concave portion of the substrate by allowing an oligomer, which contains an element contained in at least one selected from the group of the precursor gas, the first nitrogen- and hydrogen-containing gas, and the second nitrogen- and hydrogen-containing gas, to be generated, grow, and flow by performing a cycle a predetermined number of times at a first temperature, the cycle including:
supplying the precursor gas to the substrate provided with the concave portion in the surface of the substrate;
supplying the first nitrogen- and hydrogen-containing gas to the substrate;
supplying the second nitrogen- and hydrogen-containing gas to the substrate; and
supplying the first modifying gas, which includes at least one selected from the group of a gas heated to a temperature higher than a temperature of the substrate and a gas excited into a plasma state, to the substrate; and
(b) forming a film, which is obtained by modifying the oligomer-containing layer, by performing a thermal treatment to the substrate, which has the oligomer-containing layer formed on the surface of the substrate and in the concave portion of the substrate, at a second temperature equal to or higher than the first temperature to modify the oligomer-containing layer formed on the surface of the substrate and in the concave portion of the substrate so as to be filled in the concave portion.

22. A non-transitory computer-readable recording medium storing a program that causes, by a computer, a processing apparatus to perform a process comprising the method of claim 1.
